(19) United States
(12) Patent Application Publication
(10) Pub. No.: US 2013/0052476 A1
(43) Pub. Date: Feb. 28, 2013

(54) HOUSING AND METHOD FOR MAKING SAME

(71) Applicants: YONG-GANG ZHU, Shenzhen City (CN); GUI-YUN YANG, Shenzhen City (CN); XIN-WU GUAN, Shenzhen City (CN); PO-FENG HO, Shindian (TW)

(72) Inventors: YONG-GANG ZHU, Shenzhen City (CN); GUI-YUN YANG, Shenzhen City (CN); XIN-WU GUAN, Shenzhen City (CN); PO-FENG HO, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/413,225

(22) Filed: Mar. 6, 2012

(30) Foreign Application Priority Data
Aug. 30, 2011 (CN) 201110252833.3

(51) Int. Cl. B32B 1/02; B05D 7/14; C25D 7/04; B32B 3/00; C23C 14/34; B32B 15/04; C25D 5/34; C25D 5/36; C25D 5/44; C23C 28/04; B05D 3/12; B32B 15/01

(52) U.S. Cl. 428/612; 427/290; 428/34.1; 205/50; 205/208; 205/199; 204/192.15

(57) ABSTRACT

A housing includes a metal substrate having an outer surface and a color layer formed on the outer surface. The outer surface has a gradient surface roughness across at least one dimension of the outer surface. The color layer has a surface appearance corresponding with the outer surface, thereby the brightness of color of the color layer gradually changing with the location on the outer surface. A method for making the housing is also provided.

### BACKGROUND

1. Technical Field

The present disclosure relates to a housing and a method for making the housing.

2. Description of Related Art

Physical vapor deposition technologies are often used to produce housings of electronic devices with more attractive appearances. However, the decorative coatings may only have a single color and do not have the desired metallic textures.

Therefore, there is room for improvement within the art.

### BRIEF DESCRIPTION OF THE DRAWINGS

Many aspects of the process for coating a substrate and the method for making the housing can be better understood with reference to the following drawings. The components in the drawings are not necessarily drawn to scale, the emphasis instead being placed upon clearly illustrating the principles of the housing and the method. Moreover, in the drawings, like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a housing;

FIG. 2 is a schematic view showing an outer surface of a substrate of the housing shown in FIG. 1;

FIG. 3 is a schematic view showing a color layer having a gradually changing color brightness along a longitudinal axis of the housing shown in FIG. 1;

FIG. 4 is a cross-sectional view of a second exemplary embodiment of a housing;

FIG. 5 is a schematic view showing a manufacturing process of sandblasting a substrate in the method of manufacturing a housing according to an exemplary embodiment.

### DETAILED DESCRIPTION

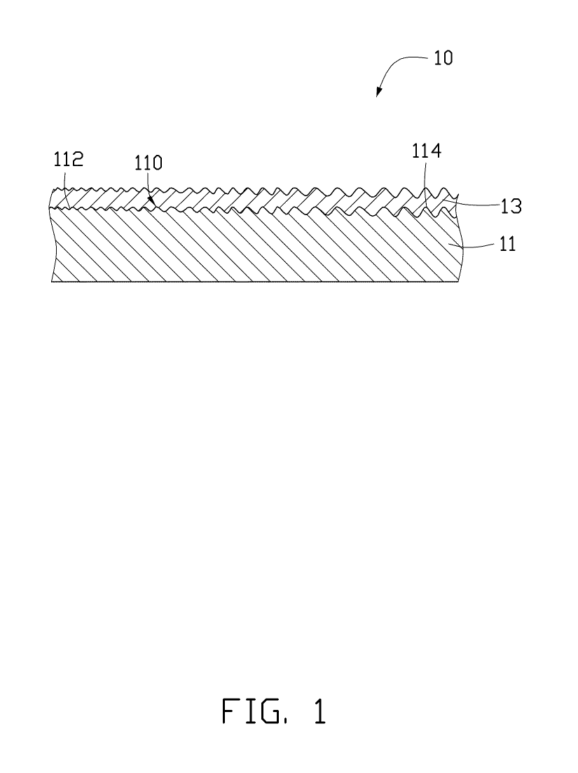

FIG. 1 shows a housing 10 according to an exemplary embodiment. The housing 10 includes a metal substrate 11 and a color layer 13 formed on the metal substrate 11.

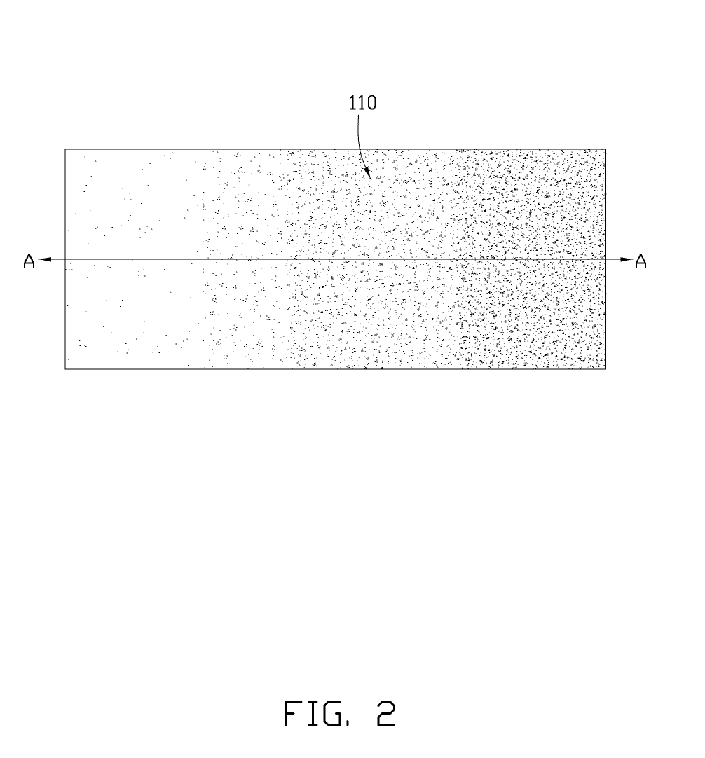

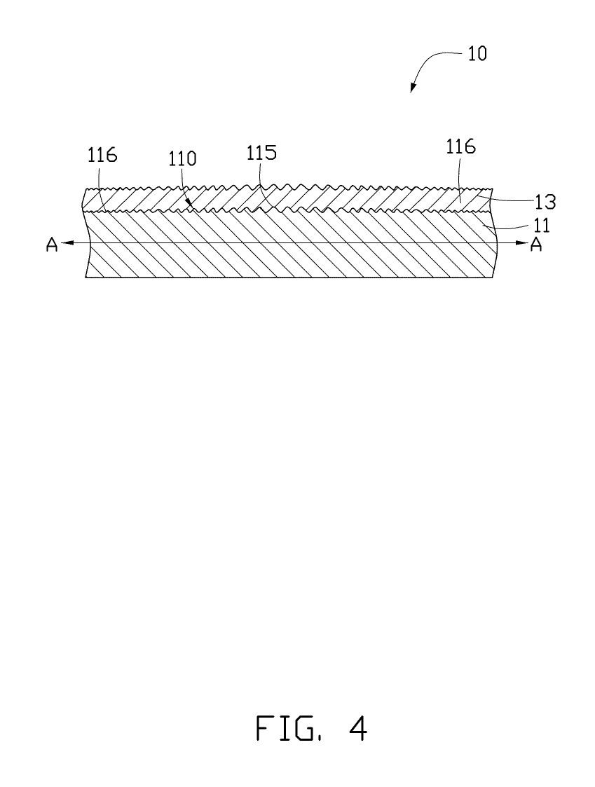

The metal substrate 11 may be made of stainless steel or aluminum alloy. The metal substrate 11 has an outer surface 110. The outer surface 110 is roughened to have a gradient surface roughness. Referring to FIG. 2, the surface roughness can gradually change (increase or decrease) from a first end 112 of the outer surface 110 to a second end 114 opposite to the first end 112 of the outer surface 110. The surface roughness of the outer surface 110 may be about 0.1 μm-2.6 μm depending upon the location on the outer surface 110 where the surface roughness measurement is taken. Referring to FIG. 4, in a second embodiment, the surface roughness can gradually change (increase or decrease) from a center 115 of the outer surface 110 to at least one periphery 116 of the outer surface 110. Again, depending upon the location on the outer surface 110 where the surface roughness measurement is taken, the surface roughness of the outer surface 110 may be about 0.1 μm-2.6 μm. That is, the surface roughness along the longitudinal axis A-A (or any other desired axis or direction) of the outer surface 110 gradually changes, from large to small or from small to large. Thereby, the outer surface 110 has a reflective pattern having a gradual brightness change on the housing 10. The larger the surface roughness the less reflection produced at that location on the outer surface 110 and the darker the color of the corresponding location looks. The surface roughness of the outer surface 110 may be resulted from a sandblasting process.

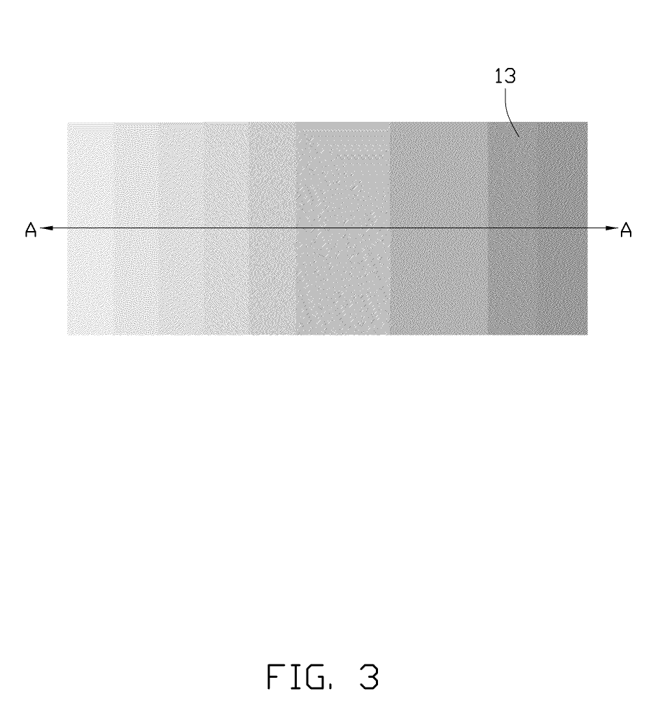

FIG. 3 shows a color layer 13 according to an exemplary embodiment. The color layer 13 may be a colored anodic oxide layer formed by an anodizing process or a metallic layer formed by physical vapor deposition. The color layer 13 is formed on the outer surface 110 and has a surface appearance that varies with the location on the outer surface 110. Thus, the brightness of the color of the color layer 13 gradually changes corresponding with the surface roughness of the outer surface 110 darkening in areas of high surface roughness and lightening in areas of low surface roughness. The color layer 13 provides a desired color for the housing 10. The color layer 13 has a thickness of about 0.5 μm to about 1 μm.

An exemplary method for making the housing 10 may include the following steps.

The metal substrate 11 is provided. The metal substrate 11 has an outer surface 110.

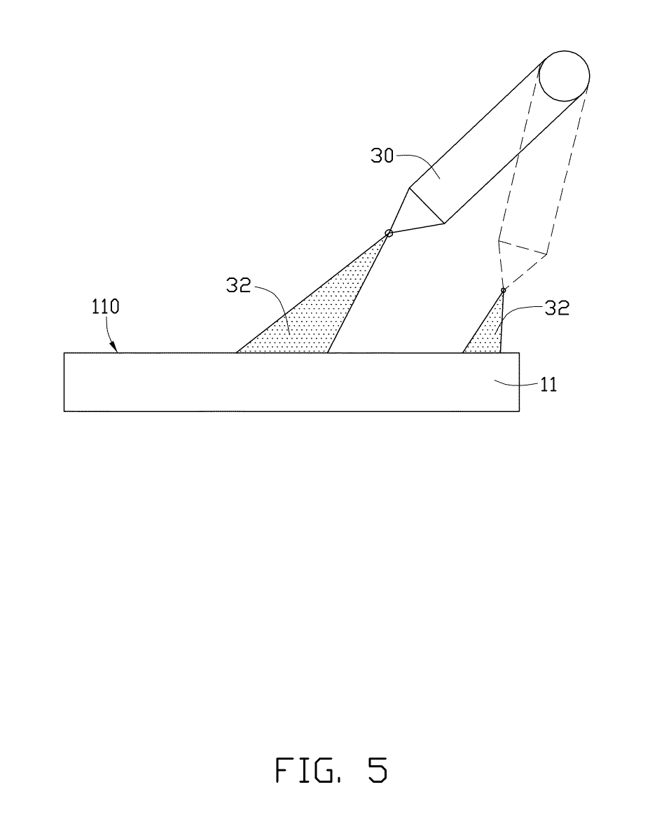

The outer surface 110 is processed, e.g., by sandblasting, achieving a gradient surface roughness thereon. Referring to FIG. 5, a spray gun 30 is used for sandblasting the outer surface 110. The spray gun 30 performs a pendulum movement with a frequency of about 5 Hz to about 50 Hz above the outer surface 110 during the sandblasting process. A plurality of sand particles 32 are sprayed out from the spray gun 30 at a spraying pressure of about 0.1 MPa to about 0.6 MPa. When the spray gun 30 moves at the highest point, the spray gun 30 has the farthest straight distance with respect to the outer surface 110. The sand particles 32 are sprayed from the spray gun 30 with a maximum force on the outer surface 110, achieving a maximum surface roughness thereon. When the spray gun 30 moves at the lowest position, the spray gun 30 has the closest straight distance with respect to the surface of metal substrate 11. The sand particles 32 are sprayed from the spray gun 30 having a minimum force to the outer surface 110, achieving a minimum surface roughness thereon. As such, the surface roughness of the outer surface 110 is gradually changed.

The color layer 13 is formed on the outer surface 110.

When the metal substrate 11 is made of aluminum alloy, the color layer 13 can be formed by anodic oxidation. An exemplary anodic oxidation process includes the following steps.

The metal substrate 11 is degreased using an alkali-based cleaning solution, removing oil stains on the metal substrate 11.

The metal substrate 11 is chemically polished. During the chemical polishing step, the metal substrate 11 is immersed in a chemical polishing solution containing phosphoric acid and sulfuric acid.

The metal substrate 11 is anodized in an electrolyte containing about 180 gram per liter (g/l) to about 200 g/l sulfuric acid and metal ions less than about 20 g/l, using a direct current of about 11 volts to about 13 volts. The anodizing takes about 30 minutes to about 50 minutes. After anodizing, an anodic oxide layer is formed on the outer surface 110. The anodic oxide layer has a surface appearance that varies with the location on the outer surface 110.

The metal substrate 11 with the anodic oxide layer is colored in a dyeing process, thereby achieving a colored anodic oxide layer. The dyeing process can be a chemical coloring process.

The metal substrate 11 is processed in a sealing process to improve the anti-contamination performance and the anti-corrosion performance of the colored anodic oxide layer. The color layer 13 formed by such method is a colored anodic oxide layer.

In another embodiment, the color layer 13 is formed by vacuum sputtering using metal target, such as zirconium. The color layer 13 formed by such method is a metallic layer.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

1. A housing, comprising:
a metal substrate having an outer surface, the outer surface having a gradient surface roughness gradually increasing or decreasing across at least one dimension of the outer surface; and
a color layer directly formed on and entirely covering the outer surface, the color layer having a surface appearance that varies with the location on the outer surface, thereby the brightness of color of the color layer gradually increasing or decreasing, to a degree varying with the location on the outer surface.

2. The housing as claimed in claim 1, wherein the brightness of the color of the color layer gradually increases or decreases corresponding with the surface roughness of the outer surface, darkening in areas of high surface roughness and lightening in areas of low surface roughness.

3. The housing as claimed in claim 2, wherein the gradient surface roughness Ra of the outer surface is about 0.1 μm to about 2.6 μm.

4. The housing as claimed in claim 3, wherein the gradient surface roughness gradually increases or decreases from a first end of the outer surface to a second end opposite to the first end of the outer surface.

5. The housing as claimed in claim 3, wherein the gradient surface roughness gradually increases or decreases from a center of the outer surface to at least one periphery of the outer surface.

6. The housing as claimed in claim 1, wherein the color layer has a thickness of about 0.5 μm to about 1 μm.

7. The housing as claimed in claim 1, wherein the color layer is a colored anodic oxide layer or a metallic layer.

8. The housing as claimed in claim 1, wherein the surface roughness gradually increases or decreases from a first end of the outer surface to a second end opposite to the first end of the outer surface.

9. The housing as claimed in claim 1, wherein the surface roughness gradually increases or decreases from a center of the outer surface to at least one periphery of the outer surface.

10. The housing as claimed in claim 1, wherein the metal substrate is made of stainless steel or aluminum alloy.

11. A method for making a housing, comprising:
providing a metal substrate having an outer surface;
sandblasting the outer surface, achieving a gradient surface roughness across at least one dimension of the outer surface; and
forming a color layer on the outer surface, the color layer having a surface appearance that varies with the location on the outer surface.

12. The method as claimed in claim 11, wherein sandblasting the outer surface uses a spray gun performing a pendulum movement with a frequency of about 5 Hz to about 50 Hz above the outer surface.

13. The method as claimed in claim 12, wherein during the sandblasting, sand particles are sprayed out from the spray gun at a spraying pressure of about 0.1 MPa to about 0.6 MPa.

14. The method as claimed in claim 11, wherein the color layer is formed by anodic oxidation.

15. The method as claimed in claim 11, wherein the anodic oxidation includes anodizing the metal substrate to form an anodic oxide layer on the outer surface and dyeing the anodic oxide layer.

16. The method as claimed in claim 11, wherein the color layer is formed by vacuum sputtering using metal target.
